(19) United States
(12) Patent Application Publication
(10) Pub. No.: US 2025/0364432 A1
(43) Pub. Date: Nov. 27, 2025

(54) MODULE AND MODULE ASSEMBLY

(71) Applicant: Murata Manufacturing Co., Ltd., Nagaokakyo-shi (JP)

(72) Inventor: Yoshihito OTSUBO, Nagaokakyo-shi (JP)

(73) Assignee: Murata Manufacturing Co., Ltd., Nagaokakyo-shi (JP)

(21) Appl. No.: 19/298,210

(22) Filed: Aug. 13, 2025

Related U.S. Application Data
(63) Continuation of application No. PCT/JP2024/002366, filed on Jan. 26, 2024.

(30) Foreign Application Priority Data
Feb. 16, 2023 (JP) 2023-022587

(51) Int. Cl. H01L 23/552; H01L 21/56; H01L 23/31; H01L 23/538; H01L 25/18

(52) U.S. Cl. CPC H01L 23/552; H01L 21/56; H01L 23/3135; H01L 23/5385; H01L 23/5386; H01L 25/18

(57) ABSTRACT

A module includes a first floor portion and a second floor portion in contact with an upper side of the first floor portion. Each of the first and second floor portions include a component group and a sealing resin sealing the component group. An interconnection is electrically connected to each component of the second component group on a lower surface of the second floor portion. A conductor pillar is in the first floor portion and extends through the first sealing resin in a thickness direction to electrically connect a lower surface of the first floor portion and the lower surface of the second floor portion. A ground conductor pattern covers at least a part of a 10 reference region. The ground conductor pattern is electrically isolated from the interconnection. The first sealing resin and the second sealing resin are in direct contact with each other in at least any part.

### CROSS-REFERENCE TO RELATED APPLICATIONS

The present application is a continuation of International Application No. PCT/JP2024/002366, filed Jan. 26, 2024, which claims priority to Japanese patent application JP 2023-022587, filed Feb. 16, 2023, the entire contents of each of which being incorporated herein by reference.

### TECHNICAL FIELD

The present disclosure relates to a module and a module assembly.

### BACKGROUND ART

In order to mount components at a high density in a module, a so-called two-story structure has been proposed. One example of such a structure is described in US2022/0037244A1 (PTL 1). In the case where the two-story structure is employed in accordance with the description of PTL 1, while components can be mounted at a high density, a substrate is required for each of the floors on which components are mounted. This results in a disadvantage that the height of the entire module is increased by the thickness of the substrate.

In contrast, US2022/0301995A1 (PTL 2) and US2022/0359418A1 (PTL 3) propose a structure in which components are mounted on a substrate, the components are sealed by resin molding, and components are further mounted on the sealing resin.

### CITATION LIST

### Patent Literature

PTL 1: US2022/0037244A1
PTL 2: US2022/0301995A1
PTL 2: US2022/0359418A1

### SUMMARY TECHNICAL PROBLEMS

It is described in the above-referenced documents that an interconnection disposed on a surface of the substrate is formed by sputtering. However, it is considered that the interconnection formed by sputtering is small in thickness and is accordingly difficult to stably exhibit its specific characteristics. In addition, in a configuration having an interconnection extending on a side surface of a module, the length of the interconnection is accordingly long, which is a disadvantageous characteristic.

In the case where the two-story structure is employed in which the second floor portion is not provided with its own substrate, how to ensure electrical insulation between the first floor portion and the second floor portion is a problem. In addition, how to ensure shielding between the first floor portion and the second floor portion is also a problem.

In view of the above, the present disclosure is directed to providing a module and a module assembly that can ensure electrical insulation and shielding between the first floor portion and the second floor portion.

### SOLUTIONS TO PROBLEMS

In order to achieve the above, a module according to the present disclosure includes: a first floor portion and a second floor portion disposed in contact with an upper side of the first floor portion. The first floor portion includes: a first component group including one or more components; and a first sealing resin sealing the first component group. The second floor portion includes: a second component group including one or more components; and a second sealing resin sealing the second component group. An interconnection electrically connected to each component of the second component group is disposed on a lower surface of the second floor portion. A conductor pillar is disposed in the first floor portion, the conductor pillar extending through the first sealing resin in a thickness direction to electrically connect a lower surface of the first floor portion and the lower surface of the second floor portion. A ground conductor pattern covers at least a part of a reference region defined by excluding, from an entire region of the lower surface of the second floor portion, the interconnection, a gap portion set along an outer contour of the interconnection, and a projection region of the second component group. The ground conductor pattern is electrically isolated from the interconnection. In at least any part, the first sealing resin and the second sealing resin are in direct contact with each other.

### Advantageous Effects

According to the present disclosure, electrical insulation between the first floor portion and the second floor portion can be ensured, and the shielding can also be ensured by disposing the ground conductor pattern.

### BRIEF DESCRIPTION OF DRAWINGS

FIG. 1 is a perspective view of a module according to Embodiment 1 based on the present disclosure.

FIG. 2 is a perspective plan view of the module according to Embodiment 1 based on the present disclosure.

FIG. 3 is a cross-sectional view taken along line III-III in FIG. 2, as seen in the direction of the arrows.

FIG. 4 is a cross-sectional view of the module according to Embodiment 1 based on the present disclosure.

FIG. 5 is a cross-sectional view of a module according to Embodiment 2 based on the present disclosure.

FIG. 6 is a perspective plan view of a module according to Embodiment 3 based on the present disclosure.

FIG. 7 is a cross-sectional view taken along line VII-VII in FIG. 6, as seen in the direction of the arrows.

FIG. 8 is a cross-sectional view of a module according to Embodiment 4 based on the present disclosure.

FIG. 9 is a perspective plan view of a module according to Embodiment 5 based on the present disclosure.

FIG. 10 is a cross-sectional view taken along line X-X in FIG. 9, as seen in the direction of the arrows.

FIG. 11 is a diagram illustrating a modification of the module according to Embodiment 5 based on the present disclosure.

FIG. 12 is a cross-sectional view of a module according to Embodiment 6 based on the present disclosure.

FIG. 13 is a perspective plan view of a module according to Embodiment 7 based on the present disclosure.

FIG. 14 is a cross-sectional view taken along line XIV-XIV in FIG. 13, as seen in the direction of the arrows.

### DESCRIPTION OF EMBODIMENTS

The dimensional ratio shown in the drawings does not necessarily represent the exact actual dimensional ratio, but may be exaggerated for convenience of illustration. In the following description, the concept “top/upper” or “bottom/lower” mentioned herein does not necessarily refer to the exact “top/upper” or “bottom/lower,” but may refer, in a relative sense, to “top/upper” or “bottom/lower” of a posture shown in the drawings.

### Embodiment 1

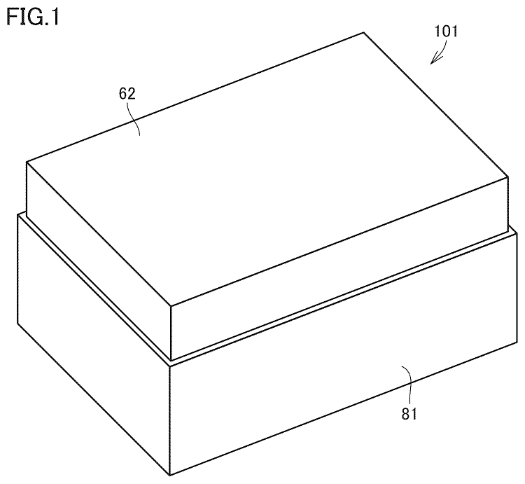

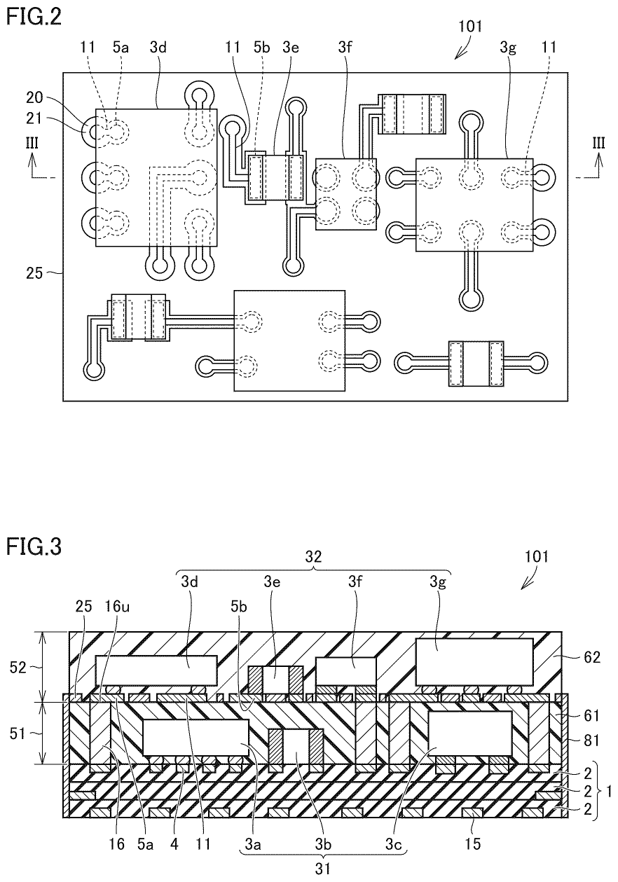

With reference to FIGS. 1 to 3, a module according to Embodiment 1 based on the present disclosure is described. FIG. 1 shows an external appearance of a module 101 according to the present embodiment. A second sealing resin 62 is exposed on the upper surface of module 101. A first shield film 81 is seen on a lower portion of the side surface of module 101. Second sealing resin 62 is exposed on an upper portion of the side surface of module 101. FIG. 2 shows a plan view of module 101. It should be noted that FIG. 2 shows a state as seen through second sealing resin 62. Therefore, in FIG. 2, components 3d, 3e, 3f, and 3g, for example, which are actually hidden by second sealing resin 62 and are therefore invisible, are indicated by solid lines. FIG. 3 shows a cross-sectional view taken along line III-III in FIG. 2, as seen in the direction of the arrows.

Module 101 according to the present embodiment includes a first floor portion 51 and a second floor portion 52 in contact with the upper side of first floor portion 51. In particular, the first floor portion 51 and the second floor portion 52 may be directly on and in physical contact with the upper side of first floor portion 51. First floor portion 51 includes: a first component group 31 including one or more components 3a, 3b, and 3c; and a first sealing resin 61 sealing first component group 31. Second floor portion 52 includes: a second component group 32 including one or more components 3d, 3e, 3f, and 3g; and a second sealing resin 62 sealing second component group 32. An interconnection 11 electrically connected to each component of second component group 32 is disposed on the lower surface of second floor portion 52. A conductor pillar 16 that extends through first sealing resin 61 in the thickness direction to electrically connect the lower surface of first floor portion 51 and the lower surface of second floor portion 52 is disposed in first floor portion 51. A ground conductor pattern 25 covers at least a part of a reference region defined by excluding, from the entire region of the lower surface of second floor portion 52, interconnection 11, a gap portion 20 set along the outer contour of interconnection 11, and a projection region where second component group 32 is projected. This configuration allows the ground conductor pattern 25 to provide shielding without electrically interfering with the interconnection 11 or the components 32 themselves. The ground conductor pattern 25 and the interconnection 11 are provided at an interface between the first floor portion 51 and the second floor portion 52 and are electrically isolated from one another. In at least any part, first sealing resin 61 and second sealing resin 62 are in direct contact with each other. In particular, the first sealing resin 61 and second sealing resin 62 may be in direct contact at the interface where the ground conductor pattern 25 and the interconnection 11 are not provided, i.e., may electrically isolate the ground conductor pattern 25 and the interconnection 11 from each other.

Module 101 includes a substrate 1. Substrate 1 includes a plurality of electrically insulating layers 2. A plurality of insulating layers 2 are stacked together. A conductor pattern may be disposed inside substrate 1. As shown in FIG. 3, the conductor pattern may be exposed on the side surface of substrate 1. The side surface of first sealing resin 61 and the side surface of substrate 1 are covered together by first shield film 81. Ground conductor pattern 25 and first shield film 81 are connected to each other. Ground conductor pattern 25 and first shield film 81 may be formed together in the same process or may be formed separately in different processes.

An external terminal 15 is provided in the lower surface of substrate 1. A terminal 4 is provided in the upper surface of substrate 1. The components belonging to first component group 31 are connected to terminal 4. Terminals 5a and 5b are provided in the lower surface of second floor portion 52. Components 3d, 3f, and 3g belonging to second component group 32 are connected to terminal 5a. Component 3e is connected to terminal 5b. Interconnection 11 extends from each of terminals 5a and 5b.

FIG. 2 shows a resist film 21 disposed in gap portion 20. In FIG. 3, resist film 21 is not shown. The same applies as well to the drawings for the following embodiments.

In the present embodiment, the so-called two-story structure of components is employed, and no substrate is disposed between first floor portion 51 and second floor portion 52, so that the height of the entire module can be reduced. In the present embodiment, conductor pillar 16 extends through first sealing resin 61 of first floor portion 51 in the thickness direction, so that the length of the interconnection can be shortened. Since first floor portion 51 is sealed by first sealing resin 61 and second floor portion 52 is sealed by second sealing resin 62, electrical insulation between first floor portion 51 and second floor portion 52 is sufficiently ensured. In the present embodiment, ground conductor pattern 25 covers at least a part of the reference region of the lower surface of second floor portion 52, and therefore, the shielding between first floor portion 51 and second floor portion 52 is also ensured.

In order to more reliably ensure the shielding between first floor portion 51 and second floor portion 52, the part of the reference region that is covered by ground conductor pattern 25 may be as large as possible. For example, the ground conductor pattern is may cover 70% or more of the reference region. By employing this configuration, it is possible to sufficiently ensure the shielding.

As illustrated above in connection with the present embodiment, the first shield film 81 may cover the side surface of first sealing resin 61, and ground conductor pattern 25 is connected to first shield film 81. By employing this configuration, the shielding for first floor portion 51 may be strengthened.

As illustrated above in connection with the present embodiment, substrate 1 may be in contact with the lower surface of first sealing resin 61. While a configuration without substrate 1 may be possible, a configuration having substrate 1 is illustrated in connection with the present embodiment. The presence of substrate 1 facilitates manufacturing. In addition, the presence of substrate 1 enables the rigidity to be increased. In contrast, a configuration without substrate 1 may be employed to reduce the height. Substrate 1 may be an LTCC (Low Temperature Co-fired Ceramic) substrate or a resin multilayer substrate.

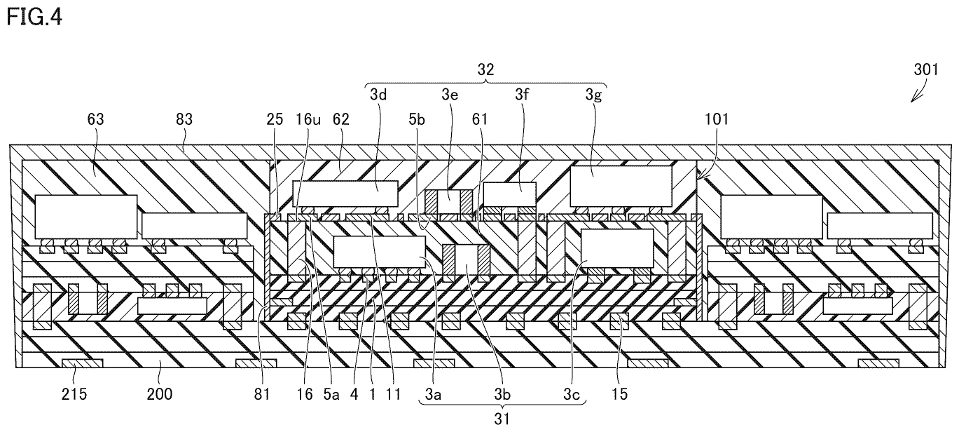

It should be noted that module 101 of the present embodiment may be mounted on a different article. FIG. 4 shows a module assembly 301 according to the present embodiment. In this example, module 101 is mounted on a mother substrate 200.

As shown in FIG. 4, module assembly 301 according to the present embodiment includes above-described module 101 and mother substrate 200, module 101 is mounted on a surface of mother substrate 200, another component (other components) is mounted on a region of the surface of mother substrate 200, other than a region of the surface thereof on which module 101 is mounted, and the other component(s) is sealed with a third sealing resin 63. By employing this configuration, it is possible to obtain the advantageous effects described above in connection with module 101, and use the module in the form of the module assembly. While module 101 and module assembly 301 are herein distinguished from each other by being referred to by different names for the sake of convenience of description, module assembly 301 may also be referred to as module. For example, module assembly 301 may be referred to as module and module 101 may be referred to as sub-module.

While the configuration where second floor portion 52 is provided with second sealing resin 62 is described above in connection with the present embodiment, a configuration where second floor portion 52 is not provided with second sealing resin 62 is also possible. In the case of such a configuration, repair of second component group 32 is facilitated.

### Embodiment 2

With reference to FIG. 5, a module according to Embodiment 2 based on the present disclosure is described. FIG. 5 shows a cross-sectional view of a module 102 according to the present embodiment. Module 102 includes a second shield film 82 in addition to first shield film 81. In module 102, second shield film 82 covers the upper surface and the side surface of second sealing resin 62.

First shield film 81 includes at least a Cu (copper) layer. First shield film 81 may have a two-layer structure of an SUS (Stainless Steel) layer and a Cu layer, for example. Second shield film 82 may have a three-layer structure of an SUS layer, a Cu layer, and an SUS layer, for example.

In the present embodiment, the advantageous effects described above in connection with Embodiment 1 can be obtained. In the present embodiment, second shield film 82 is provided in addition to first shield film 81, and therefore, it is possible to strengthen the shielding for second floor portion 52.

As illustrated above in connection with the present embodiment, second shield film 82 may extend to cover first shield film 81 on the side surface of first sealing resin 61. By employing this configuration in which the side surface of first floor portion 51 is covered by both of first shield film 81 and second shield film 82, the shielding for first floor portion 51 may be further strengthened as compared with Embodiment 1.

### Embodiment 3

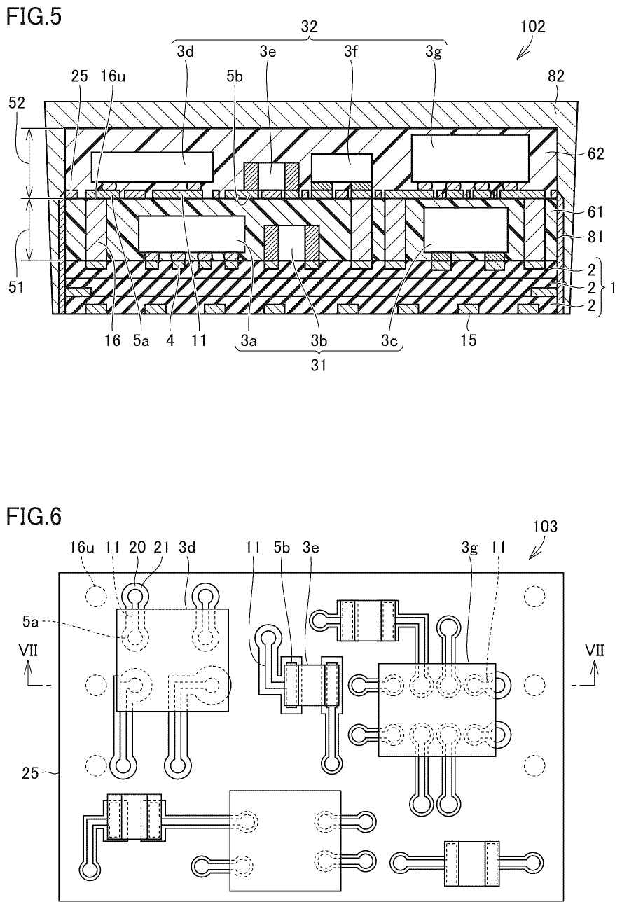

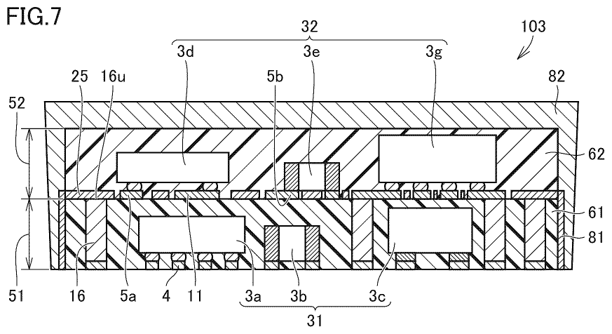

With reference to FIGS. 6 to 7, a module according to Embodiment 3 based on the present disclosure is described. FIG. 6 shows a plan view of a module 103 according to the present embodiment. It should be noted that FIG. 6 shows a state as seen through second sealing resin 62, with second shield film 82 removed from module 103. Therefore, in FIG. 6, components 3d, 3e, and 3g, for example, which are actually hidden by second shield film 82 and second sealing resin 62 and are therefore invisible, are indicated by solid lines. FIG. 7 shows a cross-sectional view taken along line VII-VII in FIG. 6, as seen in the direction of the arrows. FIG. 7 shows the cross-sectional view of module 103 in a state where second shield film 82 and second sealing resin 62 are present.

Module 103 does not include substrate 1 as illustrated above in connection with Embodiments 1 and 2. In module 103 without substrate 1, the lower surface of first floor portion 51 is directly exposed to the outside. The lower surface of first sealing resin 61 is directly exposed to the outside. Terminal 4 disposed in the lower surface of first floor portion 51 functions as an external terminal as it is.

The present embodiment corresponds to the configuration of Embodiment 2 from which substrate 1 is removed. The present embodiment also enables the advantageous effects described above in connection with Embodiment 2 to be obtained. In the present embodiment having the structure without substrate 1, the height can further be reduced as compared with Embodiment 2. By applying the concept of the present embodiment, it is possible to implement a two-story structure of components with the coreless substrate.

### Embodiment 4

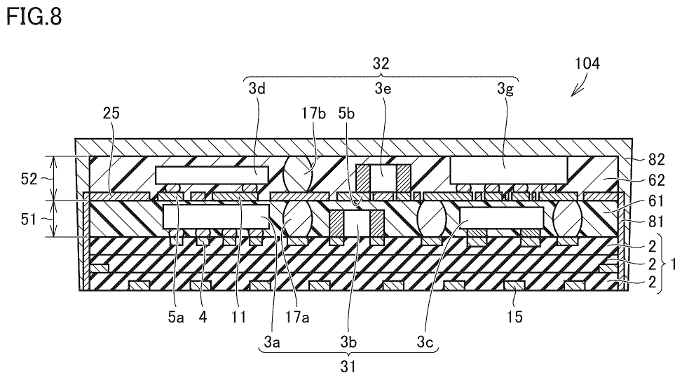

With reference to FIG. 8, a module according to Embodiment 4 based on the present disclosure is described. FIG. 8 shows a cross-sectional view of a module 104 according to the present embodiment. Module 104 includes a conductor pillar 17a instead of conductor pillar 16 illustrated above in connection with Embodiments 1 to 3. Conductor pillar 17a may be a bump. Conductor pillar 17a extends through first sealing resin 61 in the thickness direction. The lower end of conductor pillar 17a is connected to terminal 4 provided in the upper surface of substrate 1. The upper end of conductor pillar 17a is connected to ground conductor pattern 25. Therefore, terminal 4 and ground conductor pattern 25 are electrically connected to each other by conductor pillar 17a. Terminal 4 connected to the lower end of conductor pillar 17a is a terminal of a GND (ground) potential. Module 104 includes a conductor pillar 17b that extends through second sealing resin 62 in the thickness direction. Conductor pillar 17b may be a bump. The lower end of conductor pillar 17b is connected to ground conductor pattern 25. The upper end of conductor pillar 17b is connected to second shield film 82. Therefore, second shield film 82 and ground conductor pattern 25 are electrically connected to each other by conductor pillar 17b.

The present embodiment also enables advantageous effects similar to those of Embodiment 2 to be obtained. In the present embodiment, the GND potential terminal provided in the upper surface of substrate 1, ground conductor pattern 25, and second shield film 82 are electrically connected by conductor pillars 17a and 17b, and therefore, the GND connection of second shield film 82 can be strengthened.

### Embodiment 5

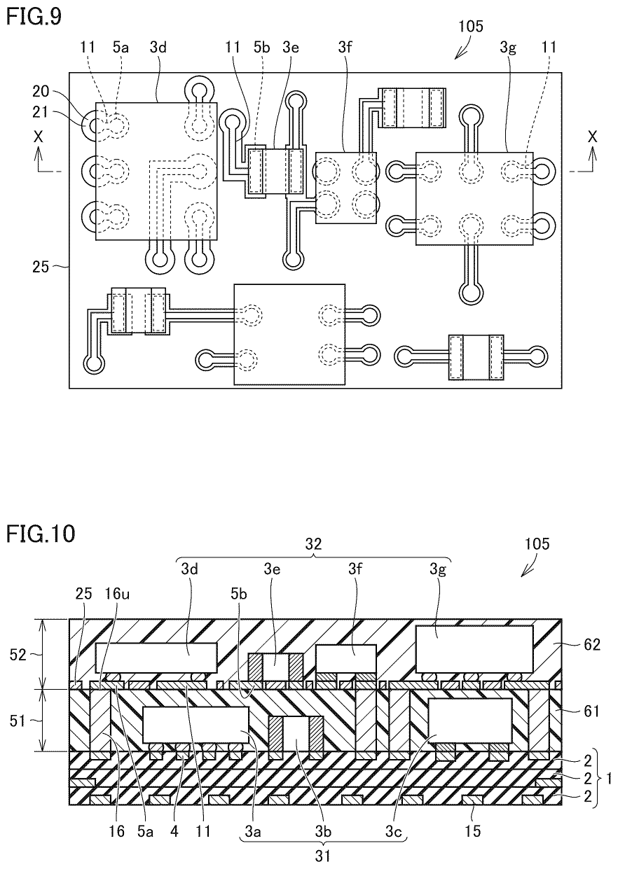

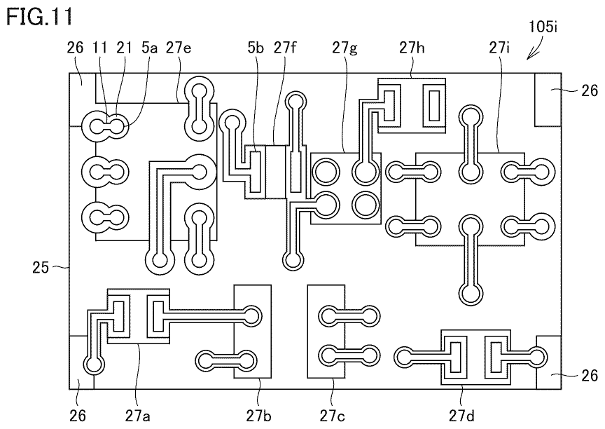

With reference to FIGS. 9 to 10, a module according to Embodiment 5 based on the present disclosure is described. FIG. 9 shows a plan view of a module 105 according to the present embodiment. It should be noted that FIG. 9 shows a state as seen through second sealing resin 62. Therefore, in FIG. 9, components 3d, 3e, and 3g, for example, which are actually hidden by second sealing resin 62 and are therefore invisible, are indicated by solid lines. FIG. 10 shows a cross-sectional view taken along line X-X in FIG. 9, as seen in the direction of the arrows. FIG. 10 shows the cross-sectional view of module 105 in a state where second sealing resin 62 is present.

Module 105 includes neither first shield film 81 nor second shield film 82. The side surface of first sealing resin 61 is exposed on the side surface of first floor portion 51. The side surface of second sealing resin 62 is exposed on the side surface of second floor portion 52.

While module 105 includes neither first shield film 81 nor second shield film 82 and therefore exhibits the shielding performance for the lateral side and the upper side that is inferior to that of the foregoing embodiments, the following configuration is still possible. The shielding between first floor portion 51 and second floor portion 52 can be ensured to some extent by ground conductor pattern 25. Module 105 also enables the advantageous effects described above in connection with the foregoing embodiments to be obtained, except that the shielding performance for the lateral side and the upper side is inferior to some extent. Since module 105 does not require the step of forming the shield films, the manufacturing process can be simplified.

It should be noted that a configuration like a module 105i shown in FIG. 11 is also possible. FIG. 11 shows a state without components, chiefly for the sake of describing a shape of ground conductor pattern 25. In module 105i, a notch portion 26 that is not covered by ground conductor pattern 25 is formed at a corner portion of the reference region. Notch portion 26 can be provided to sufficiently ensure a region where first sealing resin 61 and second sealing resin 62 are in direct contact with each other, and strengthen the bonding force between first sealing resin 61 and second sealing resin 62. As shown in FIG. 11, ground conductor pattern 25 has openings 27a, 27b, 27c, 27d, 27e, 27f, 27g, 27h, and 27i. The upper left notch portion 26 in FIG. 11 is connected to opening 27e. Thus, notch portion 26 and any of the openings may be connected to each other.

### Embodiment 6

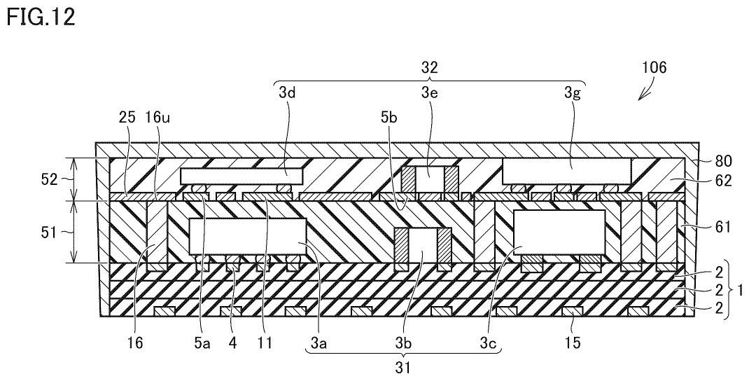

With reference to FIG. 12, a module according to Embodiment 6 based on the present disclosure is described. FIG. 12 shows a cross-sectional view of a module 106 according to the present embodiment.

In module 106, the side surface of substrate 1, the side surface of first floor portion 51, and the side surface and the upper surface of second floor portion 52 are covered together by a shield film 80. The end of ground conductor pattern 25 is connected to shield film 80.

The present embodiment also enables advantageous effects similar to those described above in connection with Embodiment 2 to be obtained.

### Embodiment 7

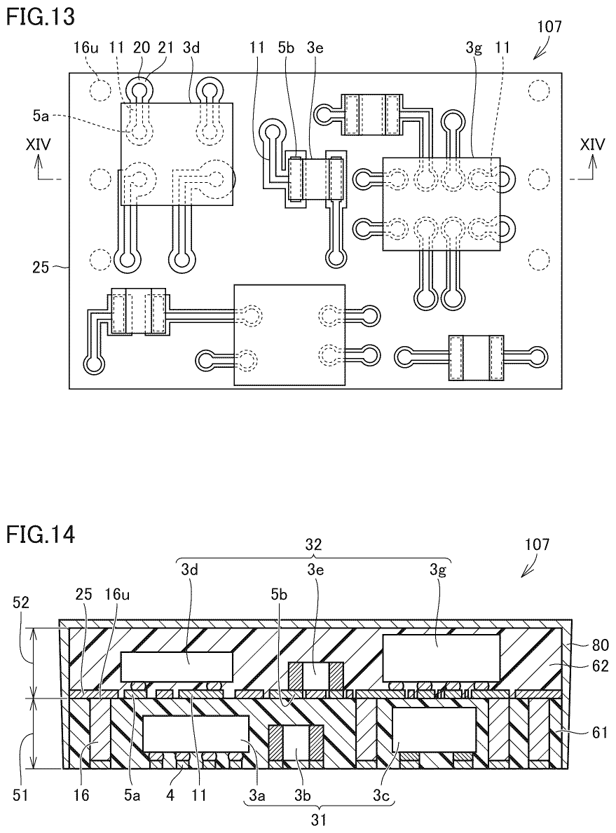

With reference to FIGS. 13 to 14, a module according to Embodiment 7 based on the present disclosure is described. FIG. 13 show a plan view of a module 107 according to the present embodiment. It should be noted that FIG. 13 shows a state as seen through second sealing resin 62, with shield film 80 removed from module 107. Therefore, in FIG. 13, components 3d, 3e, and 3g, for example, which are actually hidden by shield film 80 and second sealing resin 62 and are therefore invisible, are indicated by solid lines. FIG. 14 shows a cross-sectional view taken along line XIV-XIV in FIG. 13, as seen in the direction of the arrows. FIG. 14 shows the cross-sectional view of module 107 in a state where shield film 80 and second sealing resin 62 are present. The present embodiment corresponds to the configuration of Embodiment 6 from which substrate 1 is removed. The side surface and the upper surface of module 107 are covered by shield film 80. First sealing resin 61 is exposed on the lower surface of module 107.

The present embodiment also enables advantageous effects similar to those of Embodiment 6 to be obtained. Further, since the present embodiment does not have substrate 1, it is possible to further reduce the height.

The configurations described above in connection with the foregoing embodiments can be produced by techniques known in the art. Substrate 1 may be prepared, one or more components to be included in first component group 31 may be mounted on the surface of substrate 1, and a resin may be molded to seal first component group 31. In this way, first sealing resin 61 can be formed. Conductor pillar 16 can be formed by forming a through hole in first sealing resin 61 by laser machining or the like and filling the through hole with an electrically conductive paste or inserting a metal member in the through hole. Alternatively, components and a metal member may be mounted on substrate 1, a resin may be molded, and then polishing may be performed as required. In this way, the metal member can be formed into conductor pillar 16. Terminals 5a and 5b disposed at the boundary between first floor portion 51 and second floor portion 52 can be formed by printing a conductor pattern at the time when first floor portion 51 is formed. Alternatively, a metal foil may be adhered and then etched into an interconnection having a desired shape. Further, one or more components that are to be included in second component group 32 can be mounted thereon, and a resin can be molded to seal second component group 32, to thereby form second sealing resin 62. First shield film 81, second shield film 82, or shield film 80 can be formed by appropriately performing sputtering.

It should be noted that a plurality of embodiments out of the above-described ones may be employed in combination as appropriate.

It should be noted that the embodiments disclosed herein are given by way of illustration in all respects, not by way of limitation. It is intended that the scope of the present invention is defined by claims, and encompasses all modifications and variations equivalent in meaning and scope to the claims.

### (Supplementary Note 1)

A module including:
a first floor portion and a second floor portion disposed in contact with an upper side of the first floor portion, wherein
the first floor portion includes: a first component group including one or more components; and a first sealing resin sealing the first component group,
the second floor portion includes: a second component group including one or more components; and a second sealing resin sealing the second component group, and an interconnection electrically connected to each component of the second component group is disposed on a lower surface of the second floor portion,
a conductor pillar is disposed in the first floor portion, the conductor pillar extending through the first sealing resin in a thickness direction so as to electrically connect a lower surface of the first floor portion and the lower surface of the second floor portion,
a ground conductor pattern is disposed so as to cover at least a part of a reference region defined by excluding, from an entire region of the lower surface of the second floor portion, the interconnection, a gap portion set along an outer contour of the interconnection, and a projection region of the second component group,
the ground conductor pattern is electrically isolated from the interconnection, and
in at least any part, the first sealing resin and the second sealing resin are in direct contact with each other.

### (Supplementary Note 2)

The module according to Supplementary Note 1, wherein the ground conductor pattern is disposed so as to cover 70% or more of the reference region.

### (Supplementary Note 3)

A module according to Supplementary Note 1 or 2, wherein a notch portion that is not covered by the ground conductor pattern is formed at a corner portion of the reference region.

### (Supplementary Note 4)

The module according to any one of Supplementary Notes 1 to 3, wherein a first shield film covers a side surface of the first sealing resin, and the ground conductor pattern is connected to the first shield film.

### (Supplementary Note 5)

The module according to any one of Supplementary Notes 1 to 4, wherein a second shield film covers an upper surface and a side surface of the second sealing resin.

### (Supplementary Note 6)

The module according to any one of Supplementary Notes 1 to 3, wherein a first shield film is disposed so as to cover a side surface of the first sealing resin, the ground conductor pattern is connected to the first shield film, a second shield film is disposed so as to cover an upper surface and a side surface of the second sealing resin, and the second shield film extends so as to cover the first shield film on the side surface of the first sealing resin.

### (Supplementary Note 7)

The module according to any one of Supplementary Notes 1 to 6, wherein a substrate is disposed so as to be in contact with a lower surface of the first sealing resin.

### (Supplementary Note 8)

A module assembly including:
a module according to any one of Supplementary Notes 1 to 7; and
a mother substrate, wherein
the module is mounted on a surface of the mother substrate, and
another component is mounted on a region of the surface of the mother substrate, other than a region of the surface of the mother substrate on which the module is mounted, and the other component is sealed with a third sealing resin.

### REFERENCE SIGNS LIST

1 substrate; 2 insulating layer; 3a, 3b, 3c component; 4, 5a, 5b terminal; 11 interconnection; 15 external terminal; 16 conductor pillar; 16u upper surface (of conductor pillar); 17a, 17b (bump-type) conductor pillar; 20 gap portion; 21 resist film; 25 ground conductor pattern; 26 notch portion; 27a, 27b, 27c, 27d, 27e, 27f, 27g, 27h, 27i opening; 31 first component group; 32 second component group; 51 first floor portion; 52 second floor portion; 61 first sealing resin; 62 second sealing resin; 63 third sealing resin; 80 shield film; 81 first shield film; 82 second shield film; 83 shield film; 101, 102, 103, 104 module; 200 mother substrate; 215 external terminal; 301 module assembly.

1. A module comprising:
a first floor portion and a second floor portion disposed in contact with an upper side of the first floor portion, wherein
the first floor portion includes: a first component group including one or more components; and a first sealing resin sealing the first component group,
the second floor portion includes: a second component group including one or more components; and a second sealing resin sealing the second component group, and an interconnection electrically connected to each component of the second component group is disposed on a lower surface of the second floor portion,
a conductor pillar in the first floor portion, the conductor pillar extending through the first sealing resin in a thickness direction to electrically connect a lower surface of the first floor portion and the lower surface of the second floor portion,
a ground conductor pattern that covers at least a part of a reference region defined by excluding, from an entire region of the lower surface of the second floor portion, the interconnection, a gap portion set along an outer contour of the interconnection, and a projection region of the second component group,
the ground conductor pattern is electrically isolated from the interconnection, and
in at least any part, the first sealing resin and the second sealing resin are in direct contact with each other.

2. The module according to claim 1, wherein the ground conductor pattern covers 70% or more of the reference region.

3. The module according to claim 1, wherein a notch portion that is not covered by the ground conductor pattern is formed at a corner portion of the reference region.

4. The module of claim 3, wherein the notch portion is connected to an opening within the ground conductor pattern.

5. The module according to claim 1, further comprising a first shield film that covers a side surface of the first sealing resin, and the ground conductor pattern is connected to the first shield film.

6. The module according to claim 5, further comprising a second shield film that covers an upper surface and a side surface of the second sealing resin.

7. The module according to claim 6, further comprising a second conductor pillar extending through the second sealing resin to electrically connect the ground conductor pattern to the second shield film.

8. The module according to claim 5, wherein the first shield film conductive.

9. The module according to claim 1, wherein a first shield film covers a side surface of the first sealing resin, the ground conductor pattern is connected to the first shield film, a second shield film covers an upper surface and a side surface of the second sealing resin, and the second shield film extends to cover the first shield film on the side surface of the first sealing resin.

10. The module according to claim 1, wherein a substrate is in contact with a lower surface of the first sealing resin.

11. The module according to claim 1, further comprising a second shield film that covers an upper surface and a side surface of the second sealing resin.

12. The module according to claim 1, wherein the gap portion is filled with a resist film.

13. The module according to claim 1, wherein the module does not include a substrate, and a lower surface of the first sealing resin forms an external surface of the module.

14. A module assembly comprising:
a module according to claim 1; and
a mother substrate, wherein
the module is mounted on a surface of the mother substrate, and
another component is mounted on a region of the surface of the mother substrate, other than a region of the surface of the mother substrate on which the module is mounted, and the other component is sealed with a third sealing resin.

15. A method for manufacturing a module, the method comprising:
mounting a first component group on a surface of a substrate;
sealing the first component group with a first sealing resin to form a first floor portion;
forming a conductor pillar extending through the first sealing resin in a thickness direction;
forming an interconnection and a ground conductor pattern on an upper surface of the first floor portion, wherein the ground conductor pattern is electrically isolated from the interconnection;
mounting a second component group on the interconnection; and
sealing the second component group with a second sealing resin to form a second floor portion, wherein the second sealing resin is in direct contact with the first sealing resin.

16. The method according to claim 15, further comprising a shield film covering at least a side surface of the first floor portion, wherein the shield film is electrically connected to the ground conductor pattern.

17. A module comprising:
a first floor portion including a first component group sealed within a first resin;
a second floor portion disposed directly on the first floor portion, the second floor portion including a second component group sealed within a second resin;
an interface between the first floor portion and the second floor portion;
an interconnection disposed at the interface and electrically coupled to the second component group;
a ground conductor disposed at the interface and configured to provide electrical shielding between the first component group and the second component group; and
a conductive region extending vertically through the first resin of the first floor portion to electrically connect a lower surface of the module to the interconnection at the interface.

18. The module according to claim 17, wherein the first and second resins are in direct contact between the interconnection and the ground conductor.

19. The module according to claim 17, wherein the ground conductor is on a lower surface of the second floor portion.

20. The module according to claim 17, further comprising a shield film covering at least a side surface of the first floor portion, wherein the shield film is electrically connected to the ground conductor pattern.
